(19) United States
(12) Patent Application Publication
(10) Pub. No.: US 2017/0288705 A1
(43) Pub. Date: Oct. 5, 2017

(54) SHARED MEMORY WITH ENHANCED ERROR CORRECTION

(71) Applicant: Alibaba Group Holding Limited, George Town (KY)

(72) Inventor: Shu LI, Santa Clara, CA (US)

(21) Appl. No.: 15/091,195

(22) Filed: Apr. 5, 2016

(51) Int. Cl. H03M 13/29; G11C 29/52; G06F 11/10; G06F 13/40; G06F 13/42

(52) U.S. Cl. CPC H03M 13/2927; G06F 13/4068; G06F 13/4282; G06F 11/1068; G11C 29/52; H03M 13/2948

(57) ABSTRACT

A memory system that detects and corrects bit errors performs a first decoding procedure regarding a serial unit of the encoded data to produce a decoded serial unit. The memory system further determines the first decoding procedure regarding the serial unit was not successful and performs the first decoding procedure regarding a plurality of additional serial units of the encoded data to produce a plurality of additional decoded serial units. The serial unit and the plurality of additional serial units constitute a predefined grouping of the encoded data. The memory system also performs a second decoding procedure regarding a plurality of derivative units to produce a plurality of decoded derivative units. Each successive bit in each of the plurality of derivative units is correlated to a corresponding sequential position in the decoded serial unit and each of the decoded additional serial units.

### TECHNICAL FIELD

The present disclosure relates generally to shared memory systems and, more particularly, to shared memory using enhanced error correction coding procedures.

### BACKGROUND

Memory is used to store electronic data associated with computer systems. In general, memory can be integrated into a single computer system, such as a personal computer or a server, or consolidated in a separate memory component or appliance that is accessed by multiple computer systems. In relatively high performance computing systems, such as those typically employed in enterprise-level data analytics and database applications, memory needs to be accessible with relatively low latency and relatively high throughput. At the same time, data integrity relies on relatively high reliability and endurance. Nonetheless, large-scale deployment in data centers makes the cost of memory and important consideration.

In general, random-access memory (RAM) permits both read and write operations to currently stored data. RAM is typically used to store frequently accessed data, such as operating system (OS) and library data, as well as user data that is expected to be accessed relatively soon. Dynamic RAM (DRAM) generally permits relatively large amounts of data to be stored in a relatively small space at a relatively low cost. However, DRAM is also a relatively volatile type of memory that requires a near-continuous power supply.

Conventional systems generally designate a preset threshold memory usage level, or “watermark,” for each server, for example, between 75 percent and 90 percent. When a load monitor detects that the memory usage of a particular server is greater than the watermark level, an elastic load balancer migrates a portion of the server workload to other servers. These systems typically group as overhead all memory spaces not used for program execution among the various servers.

Typical computer software products require increasingly large quantities of memory resources. As a result, some existing systems have required individual server nodes periodically upgrade memory capacity, for example, adding memory modules. In existing systems, the central processing unit (CPU) communicates directly, or nearly directly, with DRAM. The CPU architecture typically places a practical limit on the memory capacity that can be supported. Eventually, the server platform, generally including the processor, memory modules, motherboard, and the like, are replaced with newer, higher-capacity models. In some cases, the lifetime of each generation of hardware can be shorter than desirable, potentially requiring significant repeated investment in hardware resources.

In addition, some memory components, such as DRAM memory modules, conventionally retain significant residual life at the point in time that the server platforms are retired. This can result in regular disposal of DRAM memory modules that could otherwise provide continued use. Nevertheless, as memory components continue to age the error rate in retrieved data typically will increase, which could result in an unacceptably high error rate.

### SUMMARY

According to one embodiment of the present invention, a device for detecting and correcting bit errors includes a memory that stores machine instructions and a processor coupled to the memory that executes the machine instructions to perform a first decoding procedure regarding a serial unit of the encoded data to produce a decoded serial unit. The processor further executes the instructions to determine the first decoding procedure regarding the serial unit was not successful and perform the first decoding procedure regarding a plurality of additional serial units of the encoded data to produce a plurality of additional decoded serial units. The serial unit and the plurality of additional serial units comprise a predefined grouping of the encoded data. The processor also executes the instructions to perform a second decoding procedure regarding a plurality of derivative units to produce a plurality of decoded derivative units. Each successive bit in each of the plurality of derivative units is correlated to a corresponding sequential position in the decoded serial unit and each of the decoded additional serial units. In addition, the serial unit and the additional serial units each includes a predetermined quantity of sequential bits.

According to another embodiment of the present invention, a computer-implemented method of detecting and correcting bit errors includes performing a first decoding procedure regarding a serial unit of the encoded data to produce a decoded serial unit. The method further includes determining the first decoding procedure regarding the serial unit was not successful and performing the first decoding procedure regarding a plurality of additional serial units of the encoded data to produce a plurality of additional decoded serial units. The serial unit and the plurality of additional serial units comprise a predefined grouping of the encoded data. The method also includes performing a second decoding procedure regarding a plurality of derivative units to produce a plurality of decoded derivative units. Each successive bit in each of the plurality of derivative units is correlated to a corresponding sequential position in the decoded serial unit and each of the decoded additional serial units. In addition, the serial unit and the additional serial units each includes a predetermined quantity of sequential bits.

According to yet another embodiment of the present invention, a computer program product for detecting and correcting bit errors includes a non-transitory, computer-readable storage medium encoded with instructions adapted to be executed by a processor to implement performing a first decoding procedure regarding a serial unit of the encoded data to produce a decoded serial unit. The instructions are further adapted to be executed to implement determining the first decoding procedure regarding the serial unit was not successful and performing the first decoding procedure regarding a plurality of additional serial units of the encoded data to produce a plurality of additional decoded serial units. The serial unit and the plurality of additional serial units comprise a predefined grouping of the encoded data. The instructions are also adapted to be executed to implement performing a second decoding procedure regarding a plurality of derivative units to produce a plurality of decoded derivative units. Each successive bit in each of the plurality of derivative units is correlated to a corresponding sequential position in the decoded serial unit and each of the decoded additional serial units. In addition, the serial unit and the additional serial units each includes a predetermined quantity of sequential bits.

The details of one or more embodiments of the invention are set forth in the accompanying drawings and the description below. Other features, objects, and advantages of the invention will be apparent from the description and drawings, and from the claims.

### DESCRIPTION OF THE DRAWINGS

FIG. 1 is a schematic view depicting an exemplary data center that utilizes a shared memory pool in accordance with an embodiment of the present invention.

FIG. 2 is block diagram illustrating an exemplary memory system that can be implemented in the data center of FIG. 1 in accordance with an embodiment of the present invention.

FIG. 3 is a block diagram illustrating an exemplary memory card that is compatible with the memory system of FIG. 2 in accordance with an embodiment of the present invention.

FIG. 4 is a schematic view illustrating an exemplary fabric topology that can be implemented in the memory system of FIG. 2 in accordance with an embodiment of the present invention.

FIG. 5 is an illustration representing an exemplary data error correction coding framework in accordance with an embodiment of the present invention.

FIG. 6 is a block diagram illustrating an exemplary error correction code (ECC) codec that can be implemented by the memory system of FIG. 2 in accordance with an embodiment of the present invention.

FIG. 7 is a flowchart representing an exemplary method of performing error detection and correction in accordance with an embodiment of the present invention.

### DETAILED DESCRIPTION

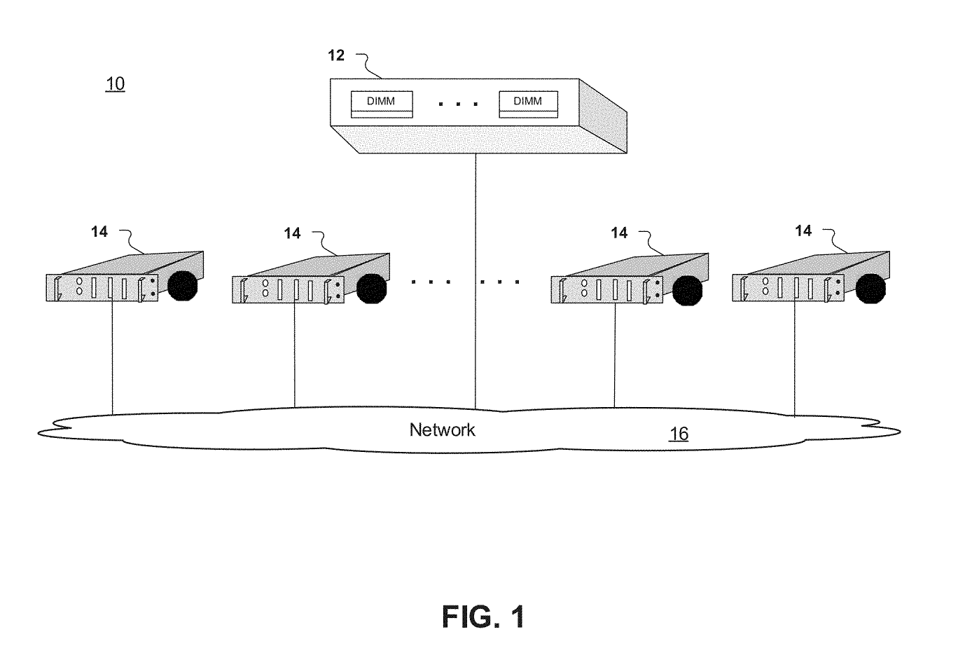

An embodiment of the present invention is shown in FIG. 1, which illustrates an exemplary data center 10 that utilizes shared memory with enhanced error correction. The data center network 10 includes a shared memory 12 and multiple servers 14, all of which are communicatively connected by a communication network 16. The shared memory system operates as a standalone component and provides a shared memory resource pool with nonvolatile storage using error detection and correction to reduce or eliminate errors in stored data. An alternative embodiment includes only a single server 14.

The shared memory 12 as implemented in the data center 10 can offer advantages, such as jointly managing memory resources among multiple servers 14 to efficiently match the total memory capacity with the resource demands of the data center 10. For example, the individual servers 14 generally reach peak memory usage at different moments in time. Thus, in an embodiment, the shared memory 12 dynamically allocates memory pages among the various servers 14, effectively allowing relatively heavily-loaded servers at any given moment in time to temporarily borrow memory space from other servers that are running at normal or relatively light load levels. In this manner, it is not necessary to equip each of the servers 14 with sufficient individual memory capacity to meet the worst case or peak load for that individual server 14.

In addition, the shared memory 12 can improve memory utilization in the data center 10. The shared memory 12 can reduce the total amount of memory capacity in the data center 10 required for overhead, such as operating system files and libraries, because a single image of any common content in each of these resources can be stored at the shared memory 12 rather than being replicated at each of the servers 14. This system overhead reduction effectively improves the practical percentage of usable memory and memory efficiency in the data center 10 with respect to distributing the physical memory modules among the individual servers 14.

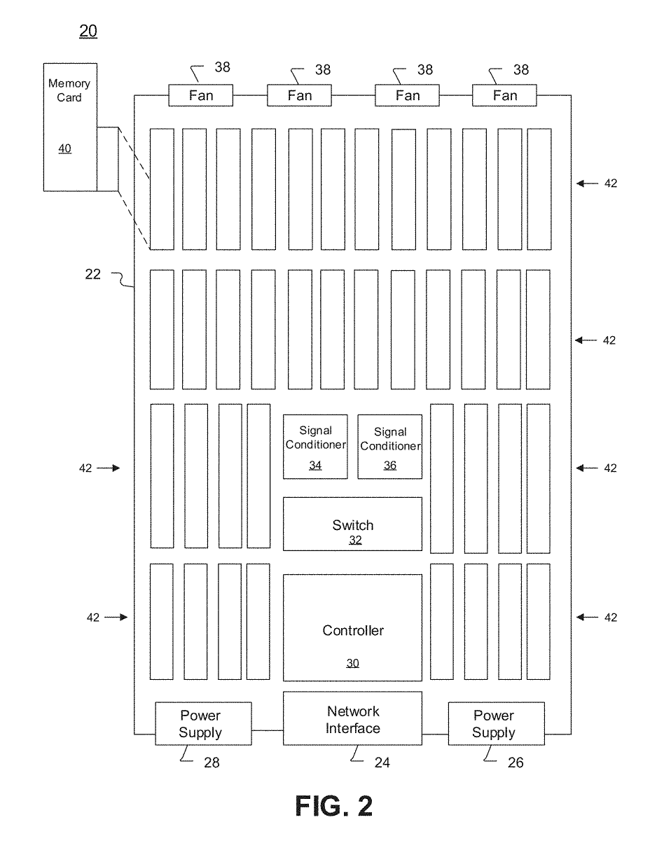

Another embodiment of the present invention is shown in FIG. 2, which illustrates the architecture of an exemplary memory system 20 that can be employed, for example, in the data center 10 of FIG. 1. The memory system 20 includes a chassis board 22, a primary power supply 26, a secondary power supply 28, a network interface 24, a system controller 30, an interconnect switch 32, a first signal conditioner 34, a second signal conditioner 36, one or more cooling fans 38, and one or more memory cards 40.

The memory system 20 implements an error detection and correction procedure in order to reduce or eliminate errors in stored data. The memory system 20 is configured to be simultaneously accessed by multiple servers as a shared memory resource. Thus, rather than inserting additional memory modules into each server, the memory modules are installed on the memory chassis to form a relatively high-capacity pool of memory shared in real time by a group of servers.

The chassis board 22, or motherboard, is based on a standard server-rack configuration form factor, for example, a 2U or 4U box that can be easily installed with rails and connected to a network, for example, by way of a top-of-rack (ToR) switch. In an embodiment, the left side of the chassis board 22 is the hot aisle, and the right side is the cold aisle.

The chassis board 22 is fitted with multiple memory card slots 42 configured to support the memory cards 40 and provide electrical power and communications connections between the memory cards 40 and other components coupled to the chassis board 22. As depicted in FIG. 2, an embodiment includes forty memory card slots 42. Alternative embodiments may include, for example, a single memory card slot, twenty-four memory card slots, sixty-two memory card slots, or any other suitable number of memory card slots.

In an embodiment, the memory card slots 42 are configured in accordance with a Peripheral Component Interconnect Express (PCIe or PCI-E) standard, for example, the PCIe 1.1 standard, the PCIe 2.0 standard or the PCIe 3.0 standard. The chassis board 22 incorporates a PCIe bus interconnecting the memory card slots 42 with the system controller 30, as well as with the other components on the chassis board 22. In other embodiments, the memory card slots 42 are configured in accordance with another serial expansion bus standard or any other suitable configuration for connecting peripheral devices.

The chassis board 22 is further fitted with appropriate physical and electrical interfaces to accommodate the network interface 24, the primary power supply 26, the secondary power supply 28, the system controller 30, the interconnect switch 32, the first signal conditioner 34, the second signal conditioner 36, the cooling fans 38, and the memory cards 40.

The primary power supply 26 and the secondary power supply 28 provide electrical power to the various other components coupled to the chassis board 22. Multiple power supplies are implemented in order to provide continuous power to the chassis board 22 in the case that a power supply should fail during operation. Thus, the memory system 20 provides increased reliability and availability with respect to a memory system implementing a single power supply. Various other embodiments may include a single power supply, three power supplies, or any suitable number of power supplies.

The network interface 24 provides for coupling of the chassis board 22 to a communication network, for example, permitting the memory system 20 to be communicatively connected to a host computer, one or more servers or workstations, or the like. In an embodiment, the network interface 24 includes a set of Ethernet ports. In various other embodiments, the network interface 24 may incorporate, for example, any combination of devices—as well as any associated software or firmware—configured to couple processor-based systems, including modems, access points, routers, network interface cards, LAN or WAN interfaces, wireless or optical interfaces and the like, along with any associated transmission protocols, as may be desired or required by the design.

The system controller 30 is mounted to the chassis board 22 and communicatively coupled to the memory card slots 42 and other components on the chassis board 22 to manage or control the memory cards 40 installed in the memory card slots 42. For example, the system controller 30 performs any necessary communication protocol conversion between the external network, such as an Ethernet protocol, and the internal memory card fabric of the memory system 20.

The system controller 30 also performs error correction to handle residual errors that cannot be corrected at the individual memory cards 40. In order to perform the functions of the memory system, the system controller 30 executes programming code, such as source code, object code or executable code, stored on a computer-readable medium, such as the memory cards 40 or a peripheral storage component coupled to the memory system 20.

The fabric design of the memory system 20 is implemented through the interconnect switch 32, or channel switch, which connects a single interconnect or link port from the system controller 30 to multiple endpoints, for example, memory cards 40 or other components on the chassis board 22. In an embodiment, the interconnect switch performs multiplexer and demultiplexer functions to route communications between the system controller 30 and multiple endpoints. For example, in an embodiment, the interconnect switch 32 is configured in accordance with a PCIe switch standard.

The first signal conditioner 34 and the second signal conditioner 36 incorporate mid-channel retimer circuitry, such as an integrated clock and data recovery circuit, to remove distortion, such as electrical jitter, and restore digital signal integrity. The signal conditioners 34, 36 improve system performance by extending the effective run length that the digital signals can reliably propagate across the chassis board 22. In an embodiment, the first and second signal conditioners 34, 36 are configured in accordance with a PCIe retimer standard. Other embodiments can implement a single signal conditioner or three or more signal conditioners.

The cooling fans 38 generate sufficient continuous or intermittent air flow to provide the convective cooling capacity required to maintain an acceptable ambient temperature for the components on the chassis board 22 during operation of the memory system 20. In an embodiment, the relatively high-density memory placement on the chassis board 22 necessitates substantial heat dissipation during operation of the memory system 20.

Multiple cooling fans 38 ensure that the cooling capacity of the memory system 20 remains effective after a cooling fan 38 has failed. As depicted in FIG. 2, an embodiment includes four cooling fans 38. Alternative embodiments include a single cooling fan 38, six cooling fans 38, or any suitable number of cooling fans 38 to provide sufficient cooling capacity for the components on the chassis board 22.

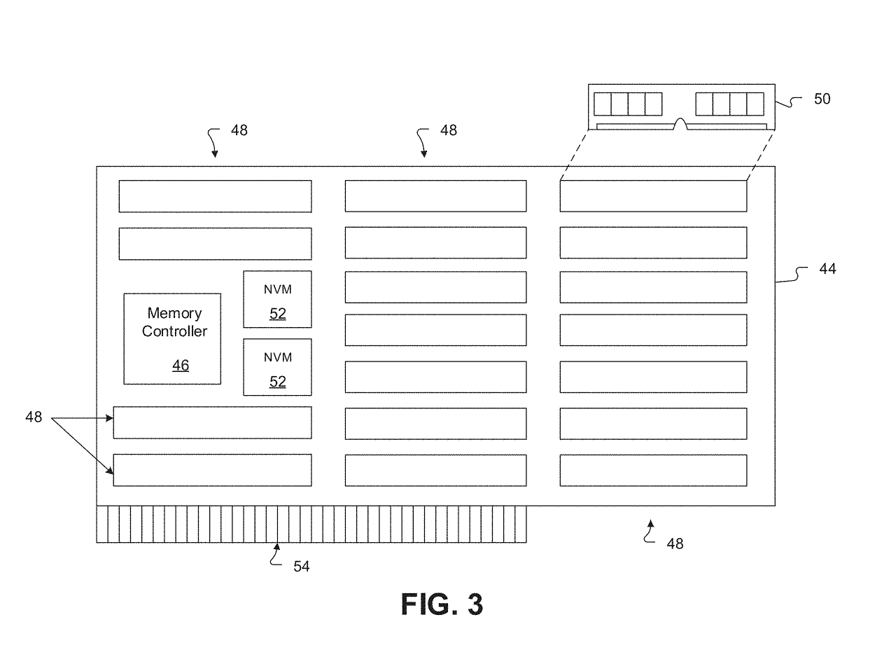

The memory cards 40 integrate one or more memory modules, such as random-access memory (RAM) modules or nonvolatile memory (NVM) modules, and are configured to be assembled with the chassis board 22. Referring to FIG. 3, an exemplary memory card 44 that can be employed, for example, in the memory system 20 of FIG. 2, includes a card controller 46, multiple memory module slots 48, one or more memory modules 50, and one or more NVM modules 52.

The memory card 44 is configured to be communicatively coupled to one of the memory card slots 42 of FIG. 2 by way of a set of electrically conductive pins 54, as known in the art. In an embodiment, the memory card 44 is configured in accordance with a PCIe standard. In this embodiment, the PCIe memory card forms the basis module of the memory pool.

The memory card 44 is based on a standard form factor that is compatible with the chassis board 22 and the memory card slots 42. An appropriate form factor may be selected based on the overall memory capacity specified for the memory system 20. For example, the memory card 44 may implement a standard half-height half-length (HHHL) card format or a standard full-height half-length (FHHL) card format, which are compatible with the 2U and 4U standard chassis, respectively.

The card controller 46 performs a protocol conversion between the memory card protocol and the memory module protocol. For example, in an embodiment, the card controller 46 performs a conversion between a standard PCIe interface protocol and a standard memory module interface protocol. In addition, the card controller 46 implements the first-level error correction regarding memory module errors.

The memory card 44 is fitted with multiple memory module slots 48 configured to support the memory modules 50 and provide electrical power and communications connections between the memory modules 50 and other components coupled to the memory card 44. As depicted in FIG. 3, an embodiment includes eighteen memory module slots 48. Alternative embodiments may include, for example, a single memory module slot, a dozen memory module slots, thirty-six memory module slots, or any other suitable number of memory module slots.

In an embodiment, the memory module slots 48 are configured in accordance with a memory module standard, for example, a dual in-line memory module (DIMM) standard, a single in-line memory module (SIMM) standard, or a double data rate (DDR) synchronous DRAM (SDRAM) standard, such as the DDR2, DDR3 or DDR4 standards.

Each memory module 50 includes one or more integrated-circuit memory chips on a circuit board. In an embodiment, the memory chips implement DRAM technology. In other embodiments the memory chips may implement any suitable RAM or NVM technology. The memory modules 50 are configured to be communicatively coupled to one of the memory module slots 48 by way of a set of electrically conductive pins, as known in the art.

In one embodiment, a set of memory modules 50 assembled into a memory card 44 primarily include previously implemented DRAM DIMMs. For example, the memory modules 50 may include DRAM DIMMs recovered from retired servers. Similarly, the memory modules 50 may include refurbished DRAM DIMMs.

The NVM modules 52 implement nonvolatile memory chips, such as NAND flash or NOR flash memory chips. The NVM modules 52 provide nonvolatile storage capacity in the case of power loss. For example, in an embodiment, when a power supply loss to the memory card 44 is detected, the card controller 46 transfers the data currently stored in the memory modules 50 into the NVM modules 52 for temporary storage until power can be restored to the memory card 44. As depicted in FIG. 3, an embodiment includes two NVM modules 52. Various other embodiments may include a single NVM module, or three or more NVM modules, as needed to provide sufficient storage capacity to back up the data stored in the memory modules 50.

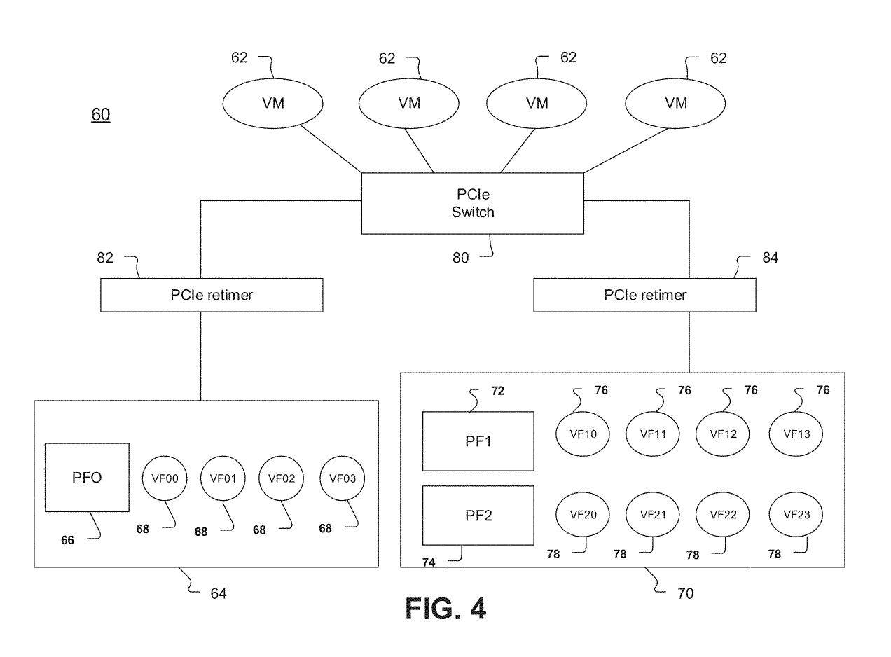

Referring to FIG. 4, an exemplary fabric topology 60 that may be implemented in an embodiment of the memory system 20 of FIG. 2. The fabric topology 60 incorporates a PCIe connection framework that is single root input/output (I/O) virtualization (SR-IOV) capable. The fabric topology 60 includes a group of virtual machines (VM) 62 coupled to an I/O virtualization (IOV) device 64 having a single physical function, PFO 66, and an IOV device 70 having multiple physical functions, PF1 72 and PF2 74, by way of a PCIe switch 80 and PCIe retimers 82, 84, respectively.

Each PCIe function is a primary entity in the PCIe bus assigned to a unique requester identifier (RID), which allows an I/O memory management unit to differentiate between different traffic streams and apply memory and interrupt translations between the physical functions and associated virtual functions. Each virtual function is dedicated to a single software entity. As is known in the art, an SR-IOV-capable device can have one or more physical functions (PF), each of which is a standard PCIe function associated with multiple virtual functions (VF). For example, the PFO 66 is associated with multiple virtual functions 68, PF1 72 is associated with multiple virtual functions 76, and PF2 is associated with multiple virtual functions 78.

As is known in the art, relatively high-density DRAM can be susceptible to bit errors due to various ambient factors such as cosmic particles, relatively warm temperatures, and relatively high humidity. Such bit errors can play a significant role regarding server performance availability in data centers. The bit error rate can increase over time as the DRAM DIMMs age. In this light, enhanced error detection and correction is implemented in an embodiment of the present invention.

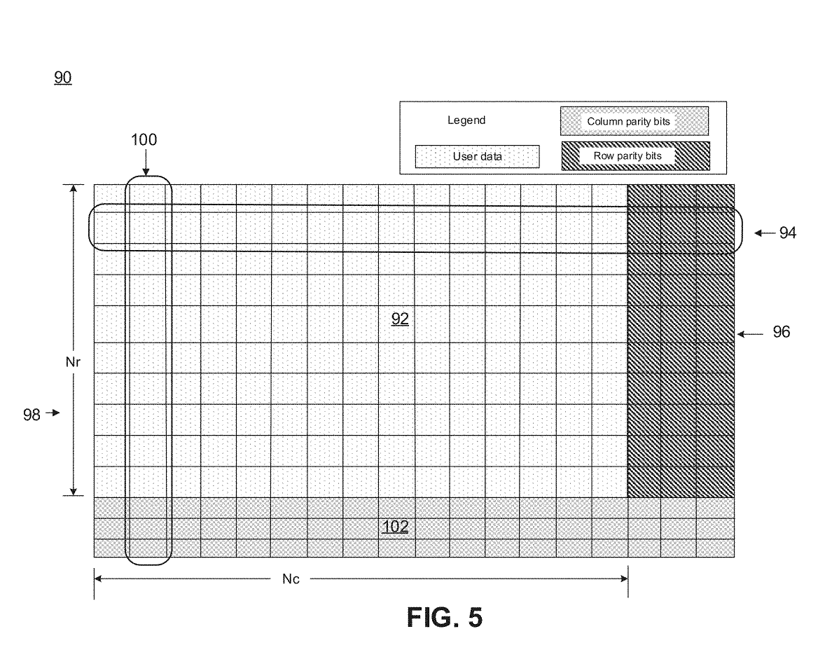

Referring to FIG. 5, an exemplary data error correction coding framework 90 is shown that can detect and reduce or eliminate bit errors in the data stored in the memory system 20 of FIG. 2. The source user data 92 is protected by column coding as well as row coding to increase error immunity. As the source user data 92 is received, each serial unit or row of data bits, such as row 94, is encoded using a row coding scheme and corresponding row parity bits 96 are generated and appended to each row.

Once all of the rows (Nr) in a selected block 98 of user data have been encoded row-by-row, each successive column of data bits from the resulting row codewords, such as column 100, is encoded using a column coding scheme and corresponding column parity bits 102 are generated and appended to each column. The column coding scheme can utilize any suitable error correcting coding scheme, such as a linear block code, Bose, Ray-Chaudhuri, and Hocquenghem (BCH) code, Reed-Solomon (RS) code, low-density parity check (LDPC) code, other forward error correction (FEC) code, or the like.

In an embodiment, the additional rows formed by the column parity bits 102 are not encoded using the row coding scheme. Thus, after all of the columns (Nc) in the selected block of data have been encoded column-by-column, the user data bits are protected by both the row code and the column code and the parity bits of the row codewords are protected by the column code.

In an embodiment, the number of rows (Nr) and the number of columns (Nc) of an encoded block, or other grouping, of data correspond to the number of bits in a physical entity, such as the number of memory cells in a physical page or block on a memory chip. In another embodiment, the number of rows and columns correspond to the size of logical entities, such as a logical page and block of data. In other embodiments, the number of rows and columns may be arbitrarily selected with regard to a data stream.

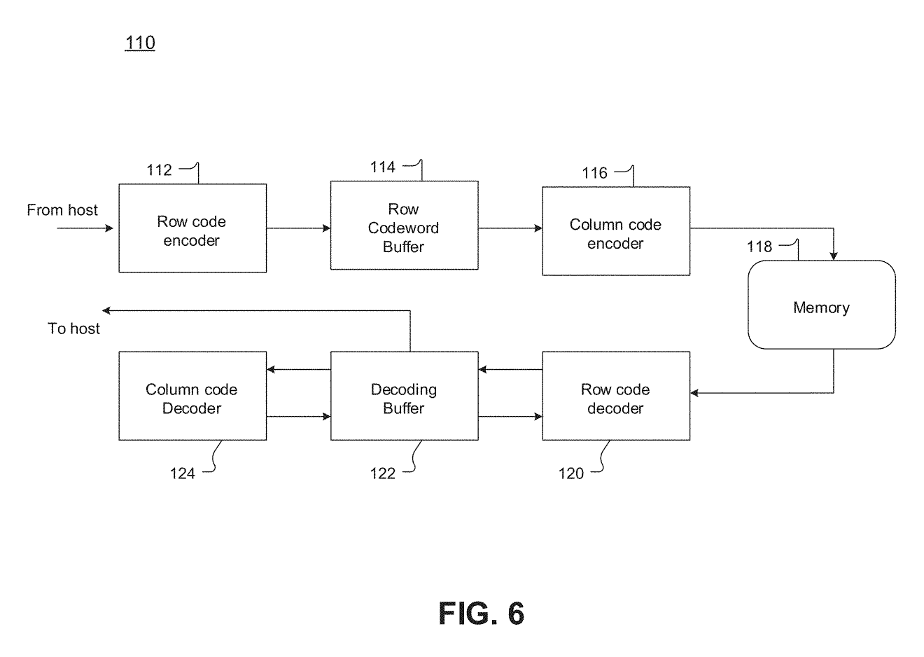

Referring to FIG. 6, an exemplary error correction code (ECC) codec 110 includes a row code encoder 112, a row codeword buffer 114, a column code encoder 116, a memory 118, a row code decoder 120, a decoding buffer 122 and a column code decoder 124. The row code encoder 112 receives a user data block from a host computer. In an embodiment, the user data block includes a defined number of row segments. In another embodiment, the row code encoder 112 divides the user data block into a number of row segments.

The row code encoder 112 encodes each of the row segments to generate row codewords including row parity bits appended to the end of each of the rows. Each row codeword corresponds to one of the rows in the user data block. The row coding scheme can utilize any suitable error correcting coding scheme, such as a linear block code, Bose, Ray-Chaudhuri, and Hocquenghem (BCH) code, Reed-Solomon (RS) code, low-density parity check (LDPC) code, other forward error correction (FEC) code, or the like.

The row codeword buffer 114 receives the generated row codewords corresponding to each of the rows and temporarily stores the row codewords. When all of the rows of the user data block have been encoded row-by-row, the column code encoder 116 forms columns from the corresponding sequential bits from each of the row segments, including the row parity bits. The column code encoder 116 encodes each of the formed columns of bits to generate column codewords including column parity bits appended to the end of each of the columns.

When all the columns of the user data block and corresponding row parity bits have been encoded column-by-column, the block of row- and column-encoded user data and parity bits is sent to memory 118. For example, in an embodiment, the column code encoder 116 further differentiates corresponding bits from each of the column codewords of the block into row codewords, including the column parity bit rows with row parity bits. The column code encoder 116 sends the block of row codewords to be sequentially stored in memory 118. After an indeterminate period of time, for example, when one or more pages of user data are requested by the host computer, the row code decoder 120 receives the row codewords corresponding to the requested pages read from memory 118.

In an alternative embodiment, the column code encoder 116 sends the generated block of column codewords to be sequentially stored in memory 118. When one or more pages of user data are requested, the entire corresponding block of column codewords are read from memory 118 and received by the row code decoder 120, which differentiates corresponding bits from each of the column codewords of the block into row codewords.

The decoding procedure proceeds in an iterative manner. The row code decoder 120 decodes the row codewords corresponding to the requested pages of user data and forwards each decoded row segment to the decoding buffer 122. If the row decoding succeeds, then the decoding buffer 122 in turn sends the requested user data to the host computer.

Otherwise, if the row decoding of one or more row codewords corresponding to the requested pages of user data is not successful, then row code decoder 120 retrieves from memory 118 and decodes the remaining rows of the corresponding block of user data. The decoded row segments are forwarded to the decoding buffer 122.

The column code decoder 124 receives the block of row segments from the decoding buffer 122 and decodes the columns of corresponding bits from each of the row segments. This column decoding procedure can recover bits that were not successfully decoded by the row code decoder 120. The resulting column segments are returned to the decoding buffer 122.

The row code decoder 120 again decodes the entire block row-by-row. This row decoding procedure can further reduce the number of bit errors. The resulting row segments are sent to the decoding buffer 122. The column code decoder 124 and the row code decoder 120 continue to iteratively repeat the column decoding and row decoding procedures until the entire block of user data is free of bit errors. After all bit errors have been corrected, either the row code decoder 120 or the column code decoder 124 terminates the decoding procedure when the decoding of all columns or all rows succeeds.

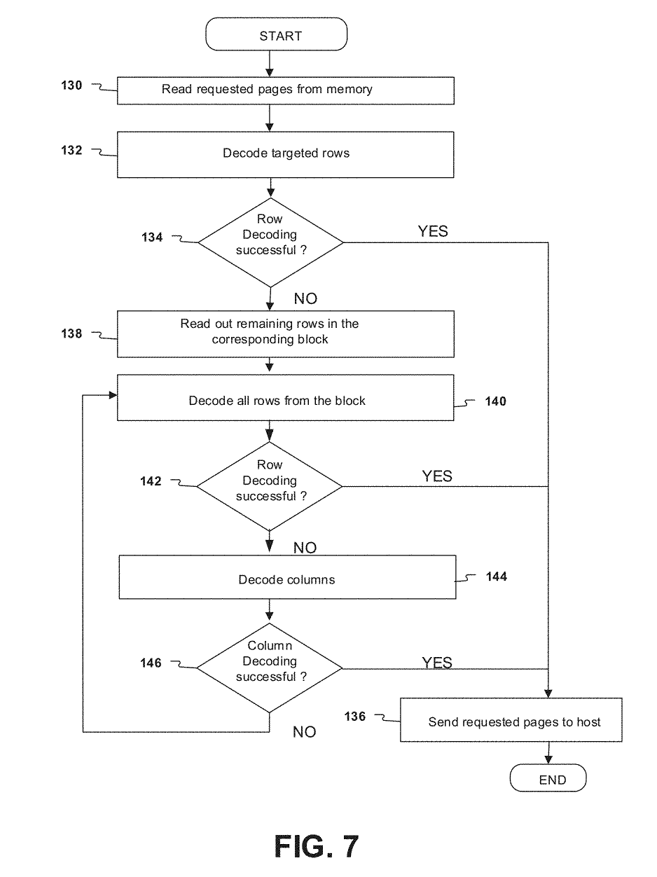

Referring now to FIG. 7, an exemplary process flow is illustrated that may be performed, for example, by the memory system 20 of FIG. 2 to implement an embodiment of the method described in this disclosure for a decoding procedure for detecting and correcting bit errors. The process begins at block 130, where one or more pages, or sequential bits, of encoded data requested by a host computer are read from corresponding physical locations in memory.

In block 132, the targeted rows, or serial units, of encoded data corresponding to the requested pages in memory are decoded using a row decoding procedure, as explained above. A determination is made, in block 134, regarding whether or not the row decoding of the targeted rows of encoded data succeeded. If the row decoding was successful, the decoded pages are sent to the requesting host computer, in block 136.

Otherwise, if the row decoding was not successful, the rest of the rows of encoded data that correspond to the same block, or other grouping, of memory cells are read from memory, in block 138. All of the rows corresponding to the memory block, including the targeted rows as well as the additional rows, are decoded using the row decoding procedure, in block 140. A determination is made, in block 142, as to whether or not the row decoding succeeded with regard to all rows in the block. If the row decoding was successful, the decoded pages are sent to the requesting host computer, in block 136.

Otherwise, if the row decoding was not successful with respect to all rows in the memory block, decoding is performed using a column decoding procedure, in block 144. Specifically, each row of the memory block is divided into individual bits, and the corresponding bit from the same location, or position, in each row of the block is placed in sequence to form a column, or derivative unit.

In block 146, a determination is made regarding whether or not all of the columns in the memory block were successfully decoded. If the column decoding was successful, the decoded targeted rows are sent to the requesting host computer, in block 136. Otherwise, if the column decoding was not successful with respect to all columns in the block, the process continues at block 140 and iteratively performs row decoding and column decoding regarding the data from the memory block, as explained above, until the decoding succeeds.

Thus, the disclosed error correction scheme iteratively works on the row code decoding and the column code decoding so that any bits corrected in either dimension accelerate the decoding on the other dimension. The disclosed error correction scheme offers advantages, for example, neither the row codec nor the column codec is particularly complex in terms of latency, hardware cost, and implementation difficulty. Nevertheless, coupling the functions of the row and column codecs at multiple dimensions can achieve improved protection with respect to a relatively high error-rate memory pool.

The disclosed memory system is characterized by relatively high capacity, low latency, high throughput, nonvolatile storage, available at a relatively low cost. The shared memory chassis decouples the dependence of existing systems on a particular central processing unit (CPU) and motherboard platform. The design and implementation of this memory pool system make it feasible for practical adoption in hyperscale infrastructure.

Aspects of this disclosure are described herein with reference to flowchart illustrations or block diagrams, in which each block or any combination of blocks can be implemented by computer program instructions. The instructions may be provided to a processor of a general purpose computer, special purpose computer, or other programmable data processing apparatus to effectuate a machine or article of manufacture, and when executed by the processor the instructions create means for implementing the functions, acts or events specified in each block or combination of blocks in the diagrams.

In this regard, each block in the flowchart or block diagrams may correspond to a module, segment, or portion of code that includes one or more executable instructions for implementing the specified logical function(s). It should also be noted that, in some alternative implementations, the functionality associated with any block may occur out of the order noted in the figures. For example, two blocks shown in succession may, in fact, be executed substantially concurrently, or blocks may sometimes be executed in reverse order.

A person of ordinary skill in the art will appreciate that aspects of this disclosure may be embodied as a device, system, method or computer program product. Accordingly, aspects of this disclosure, generally referred to herein as circuits, modules, components or systems, or the like, may be embodied in hardware, in software (including source code, object code, assembly code, machine code, micro-code, resident software, firmware, etc.), or in any combination of software and hardware, including computer program products embodied in a computer-readable medium having computer-readable program code embodied thereon.

It will be understood that various modifications may be made. For example, useful results still could be achieved if steps of the disclosed techniques were performed in a different order, and/or if components in the disclosed systems were combined in a different manner and/or replaced or supplemented by other components. Accordingly, other implementations are within the scope of the following claims.

What is claimed is:

1. A device for detecting and correcting bit errors, comprising:
a memory that stores machine instructions; and
a processor coupled to the memory that executes the machine instructions to
perform a first decoding procedure regarding a serial unit of the encoded data to produce a decoded serial unit,
determine whether or not the first decoding procedure regarding the serial unit was successful,
in response to determining the first decoding procedure regarding the serial unit was not successful, perform the first decoding procedure regarding a plurality of additional serial units of the encoded data to produce a plurality of additional decoded serial units, the serial unit and the plurality of additional serial units comprising a predefined grouping of the encoded data, and
perform a second decoding procedure regarding a plurality of derivative units to produce a plurality of decoded derivative units, each successive bit in each of the plurality of derivative units correlated to a corresponding sequential position in the decoded serial unit and each of the decoded additional serial units, wherein the serial unit and the additional serial units each includes a predetermined quantity of sequential bits.

2. The device of claim 1, wherein the processor further executes the machine instructions to determine whether or not the second decoding procedure regarding the plurality of derivative units was successful, perform a first iterative decoding procedure regarding a series of serial units corresponding to the plurality of decoded derivative units to produce an updated series of decoded serial units based on having determined the second decoding procedure regarding the plurality of derivative units was not successful, determine whether or not the first iterative decoding procedure regarding the series of serial units was successful, and perform a second iterative decoding procedure regarding a second plurality of derivative units to produce an updated plurality of decoded derivative units based on having determined the first iterative decoding procedure regarding the series of serial units was not successful, each successive bit in each of the second plurality derivative units correlated to a corresponding sequential position in each of the updated series of decoded serial units.

3. The device of claim 2, wherein the processor further executes the machine instructions to continue to perform the first iterative decoding procedure regarding successive resulting series of serial units and the second iterative decoding procedure regarding successive resulting derivative units until the encoded data is successfully decoded, and send the decoded serial unit corresponding to the successful resulting series of serial units to a host computer.

4. The device of claim 2, wherein the processor further executes the machine instructions to store the updated series of decoded serial units in a buffer, store the updated plurality of decoded derivative units in the buffer, determine one of the first iterative decoding procedure and the second iterative decoding procedure was successful, and send the decoded serial unit corresponding to the updated series of decoded serial units to a host computer.

5. The device of claim 1, wherein the processor further executes the machine instructions to read the serial unit from a series of memory cells in a memory, wherein the serial unit corresponds to a page of stored data in the memory and the grouping corresponds to a block of stored data in the memory.

6. The device of claim 1, wherein the processor further executes the machine instructions to encode a series of segments of user data to produce a plurality of extensions of parity bits, each extension of the plurality of extensions of parity bits based on a respective segment in the series, append each of the plurality of extensions of parity bits to the respective segment to form the serial unit of the encoded data and the plurality of additional serial units of the encoded data, wherein the serial unit and the plurality of additional serial units include a plurality of row codewords, encode a plurality of derivative segments to produce a plurality of pendent strings of parity bits, each successive bit in each of the plurality of derivative segments correlated to a corresponding sequential position in the serial unit and each of the additional serial units, concatenate individual bits corresponding to consecutive sequential positions in each of the pendent strings of parity bits to form parity segments, the plurality of derivative segments and the corresponding plurality of pendent strings of parity bits forming the plurality of derivative units, wherein each of the plurality of derivative units include a plurality of column codewords, and send the plurality of row codewords and the plurality of column codewords to the memory.

7. The device of claim 1, wherein the first decoding procedure implements an error correction code and the second decoding procedure implements the error correction code.

8. The device of claim 1, wherein the first decoding procedure implements a first error correction code and the second decoding procedure implements a second error correction code that differs from the first error correction code.

9. The device of claim 1, wherein the memory comprises a plurality of dynamic random-access memory (DRAM) dual in-line memory modules (DIMMs) coupled to a plurality of memory cards configured in accordance with a Peripheral Component Interconnect Express (PCIe or PCI-E) standard.

10. A method of detecting and correcting bit errors, comprising:
performing a first decoding procedure regarding a serial unit of the encoded data to produce a decoded serial unit;
determining the first decoding procedure regarding the serial unit was not successful;
performing the first decoding procedure regarding a plurality of additional serial units of the encoded data to produce a plurality of additional decoded serial units, the serial unit and the plurality of additional serial units comprising a predefined grouping of the encoded data; and
performing a second decoding procedure regarding a plurality of derivative units to produce a plurality of decoded derivative units, each successive bit in each of the plurality of derivative units correlated to a corresponding sequential position in the decoded serial unit and each of the decoded additional serial units, wherein the serial unit and the additional serial units each includes a predetermined quantity of sequential bits.

11. The method of claim 10, further comprising:
determining whether or not the second decoding procedure regarding the plurality of derivative units was successful;
performing a first iterative decoding procedure regarding a series of serial units corresponding to the plurality of decoded derivative units to produce an updated series of decoded serial units based on having determined the second decoding procedure regarding the plurality of derivative units was not successful;
determining whether or not the first iterative decoding procedure regarding the series of serial units was successful; and
performing a second iterative decoding procedure regarding a second plurality of derivative units to produce an updated plurality of decoded derivative units based on having determined the first iterative decoding procedure regarding the series of serial units was not successful, each successive bit in each of the second plurality derivative units correlated to a corresponding sequential position in each of the updated series of decoded serial units.

12. The method of claim 11, further comprising:
continuing to perform the first iterative decoding procedure regarding successive resulting series of serial units and the second iterative decoding procedure regarding successive resulting derivative units until the encoded data is successfully decoded; and
sending the decoded serial unit corresponding to the successful resulting series of serial units to a host computer.

13. The method of claim 11, further comprising:
storing the updated series of decoded serial units in a buffer;
storing the updated plurality of decoded derivative units in the buffer;
determining one of the first iterative decoding procedure and the second iterative decoding procedure was successful; and
sending the decoded serial unit corresponding to the updated series of decoded serial units to a host computer.

14. The method of claim 10, further comprising reading the serial unit from a series of memory cells in a memory, wherein the serial unit corresponds to a page of stored data in the memory and the grouping corresponds to a block of stored data in the memory.

15. The method of claim 10, further comprising:
encoding a series of segments of user data to produce a plurality of extensions of parity bits, each extension of the plurality of extensions of parity bits based on a respective segment in the series;
appending each of the plurality of extensions of parity bits to the respective segment to form the serial unit of the encoded data and the plurality of additional serial units of the encoded data, wherein the serial unit and the plurality of additional serial units include a plurality of row codewords;
encoding a plurality of derivative segments to produce a plurality of pendent strings of parity bits, each successive bit in each of the plurality of derivative segments correlated to a corresponding sequential position in the serial unit and each of the additional serial units;
concatenating individual bits corresponding to consecutive sequential positions in each of the pendent strings of parity bits to form parity segments, the plurality of derivative segments and the corresponding plurality of pendent strings of parity bits forming the plurality of derivative units, wherein each of the plurality of derivative units include a plurality of column codewords; and
sending the plurality of row codewords and the plurality of column codewords to the memory.

16. The method of claim 10, wherein the first decoding procedure implements an error correction code and the second decoding procedure implements the error correction code.

17. The method of claim 10, wherein the first decoding procedure implements a first error correction code and the second decoding procedure implements a second error correction code that differs from the first error correction code.

18. The method of claim 10, wherein the memory comprises a plurality of dynamic random-access memory (DRAM) dual in-line memory modules (DIMMs) coupled to a plurality of memory cards configured in accordance with a Peripheral Component Interconnect Express (PCIe or PCI-E) standard.

19. A computer program product for detecting and correcting bit errors, comprising:
a non-transitory, computer-readable storage medium encoded with instructions adapted to be executed by a processor to implement:
performing a first decoding procedure regarding a serial unit of the encoded data to produce a decoded serial unit;
determining the first decoding procedure regarding the serial unit was not successful;
performing the first decoding procedure regarding a plurality of additional serial units of the encoded data to produce a plurality of additional decoded serial units, the serial unit and the plurality of additional serial units comprising a predefined grouping of the encoded data; and
performing a second decoding procedure regarding a plurality of derivative units to produce a plurality of decoded derivative units, each successive bit in each of the plurality of derivative units correlated to a corresponding sequential position in the decoded serial unit and each of the decoded additional serial units, wherein the serial unit and the additional serial units each includes a predetermined quantity of sequential bits.

20. The computer program product of claim 19, wherein the instructions are further adapted to implement:
determining whether or not the second decoding procedure regarding the plurality of derivative units was successful;
performing a first iterative decoding procedure regarding a series of serial units corresponding to the plurality of decoded derivative units to produce an updated series of decoded serial units based on having determined the second decoding procedure regarding the plurality of derivative units was not successful;
determining whether or not the first iterative decoding procedure regarding the series of serial units was successful;
performing a second iterative decoding procedure regarding a second plurality of derivative units to produce an updated plurality of decoded derivative units based on having determined the first iterative decoding procedure regarding the series of serial units was not successful, each successive bit in each of the second plurality derivative units correlated to a corresponding sequential position in each of the updated series of decoded serial units;
continuing to perform the first iterative decoding procedure regarding successive resulting series of serial units and the second iterative decoding procedure regarding successive resulting derivative units until the encoded data is successfully decoded; and
sending the decoded serial unit corresponding to the successful resulting series of serial units to a host computer.
